(19) United States
(12) Patent Application Publication
(10) Pub. No.: US 2012/0049920 A1
(43) Pub. Date: Mar. 1, 2012

(54) IQ SIGNAL GENERATION CIRCUIT

(75) Inventor: Satoshi Kurachi, Kanagawa-ken (JP)

(73) Assignee: KABUSHIKI KAISHA TOSHIBA, Tokyo (JP)

(21) Appl. No.: 13/051,168

(22) Filed: Mar. 18, 2011

(30) Foreign Application Priority Data
Aug. 27, 2010 (JP) 2010-190968

(51) Int. Cl. H03H 11/16

(52) U.S. Cl. 327/254

(57) ABSTRACT

According to one embodiment, an IQ signal generation circuit includes an RC poly-phase filter, a resistive load circuit and the transconductance amplifier. The RC poly-phase filter has first to fourth input terminals and first to fourth output terminals. The first and second input terminals receive first signals with a phase difference of 0°. The third and fourth input terminals receive second signals with a phase difference of 180°. The first to fourth output terminals output signals with phase differences of 0°, 90°, 180° and 270°. The resistive load circuit is connected between the first to fourth output terminals and a power supply terminal. The transconductance amplifier is connected between the first to fourth input terminals and a reference voltage terminal. The transconductance amplifier receives input signals, amplifies the input signals and generates the amplified signals to the first to fourth input terminals.

### CROSS-REFERENCE TO RELATED APPLICATION(S)

This application is based upon and claims the benefit of priority from the prior Japanese Patent Application No. 2010-190968, filed on Aug. 27, 2010, the entire contents of which are incorporated herein by reference.

### FIELD

Embodiments described herein relate generally to an IQ signal generation circuit.

### BACKGROUND

An IQ modulation circuit and an IQ demodulation circuit are used in communication equipment etc. The IQ modulation circuit and IQ demodulation circuit divide a received signal into I and Q signals so as to vector-modulate and vector-demodulate the same. The I signal indicates an in-phase signal, and the Q signal indicates a signal having a phase shifted by 90° from the I signal.

As the IQ signal generation circuit, a frequency multiplier and a frequency divider are known. The frequency multiplier multiplies a signal from a voltage controlled oscillator (VCO). The frequency divider divides a multiplied signal from VCO. The IQ signal generation circuit divides a multiplied signal at a rising timing and dropping timing of the multiplied signal. By the dividing frequency, four-phase signals with phase differences of 0°, 90°, 180° and 270° are obtained. The four-phase signals have a phase difference of 90° between each other.

However, since the IQ signal generation circuit is composed of many nonlinear elements such as transistors, which causes the phase error of generated IQ signals.

On the other hand, another IQ signal generation circuit which has a four-phase input/output RC polyphase filter is known. The four-phase input/output RC poly-phase filter receives signals with phase differences of 0° and 180°, and produces signals with phase difference of 0°, 90°, 180° and 270°.

The IQ signal generation circuit with the four phase input/output RC polyphase filter is composed of linear elements, so that the phase error of the IQ signals becomes small. Though, the level of the generated IQ signals is low. For that reason, it is necessary to provide an amplifier between the IQ signal generation circuit and a mixer. The amplifier adjusts levels of the IQ signals However, phase errors of the IQ signals occur at an input terminal of the mixer due to a nonlinear characteristic of the amplifier.

Further, the IQ signal generation circuit can not generate four-phase signals with phase difference of 90° between each other for a desired frequency, due to production tolerance of the linear elements.

### BRIEF DESCRIPTION OF THE DRAWINGS

FIG. 1 shows a circuit diagram of an IQ signal generation circuit according to a first embodiment;

FIG. 2 depicts an explanatory diagram of an example of input/output signals of a poly-phase filter provided in the IQ signal generation circuit of the first embodiment;

FIG. 3 shows a circuit diagram showing a constant current source provided in the IQ signal generation circuit of the first embodiment;

FIG. 4 shows a diagram phase characteristics of an IQ signal generated by the first embodiment;

FIG. 5 shows a block diagram of an example of an IQ modulation/demodulation circuit using the IQ signal generation circuit of the first embodiment;

FIG. 6 shows a circuit diagram of another IQ signal generation circuit according to the first embodiment;

FIG. 7 shows a circuit diagram a poly-phase filter provided in an IQ signal generation circuit according to a second embodiment; and

FIG. 8 shows a circuit diagram a transconductance amplifier provided in an IQ signal generation circuit according to a third embodiment.

### DETAILED DESCRIPTION

According to one embodiment, an IQ signal generation circuit is provided. The IQ signal generation circuit has an RC polyphase filter, a resistance load circuit and the transconductance amplifier.

The RC poly-phase filter has first to fourth input terminals and first to fourth output terminals, and resistors and capacitors respectively connected between the first to fourth input terminals and the first to fourth output terminals. The first and second input terminals receive first signals with a phase difference of 0°. The third and fourth input terminals receive second signals with a phase difference of 180°. The first to fourth output terminals output first to fourth output signals. The first to fourth output terminals output first to fourth output signals with phase differences of 0°, 90°, 180° and 270°.

The resistive load circuit is connected between the first to fourth output terminals of the poly-phase filter and a power supply terminal. The transconductance amplifier is connected between the first to fourth input terminals and a reference voltage terminal to receive third and fourth input signals corresponding to the first and second signals. The transconductance amplifier amplifies the third and fourth input signals and generates the amplified signals to the first and second input terminals, and to the third and fourth input terminals, respectively.

Hereinafter, further embodiments will be described with reference to the drawings.

In the drawings, the same reference numerals denote the same or similar portions respectively.

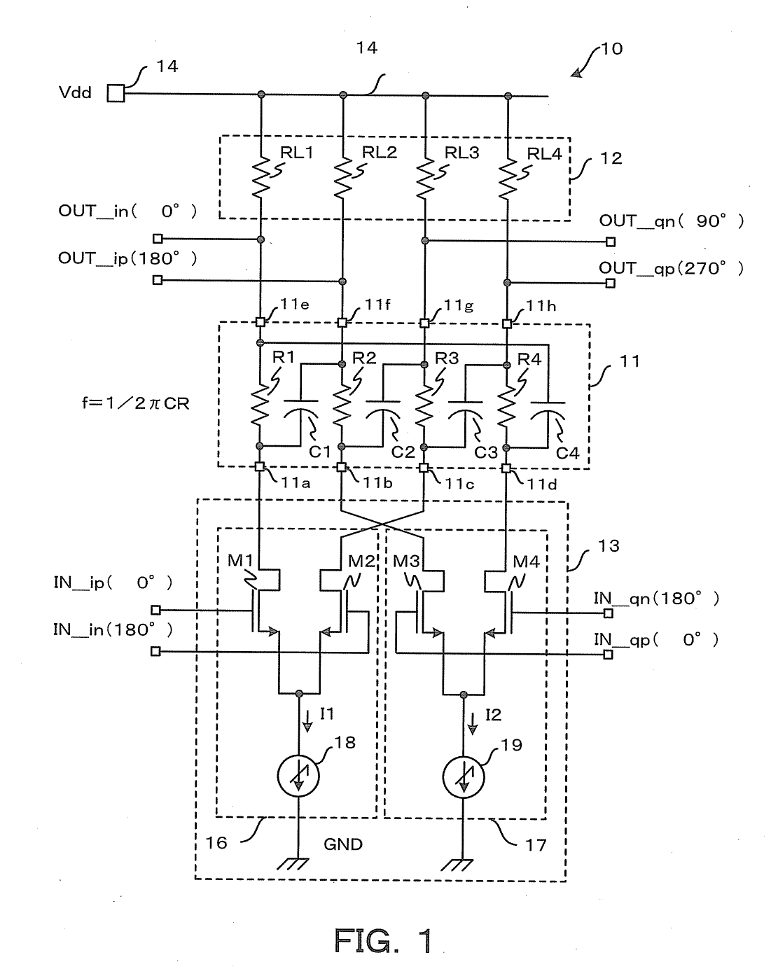

A first embodiment will be described with reference to FIGS. 1 to 3. FIG. 1 shows a circuit diagram of an IQ signal generation circuit of a first embodiment.

As shown in FIG. 1, the IQ signal generation circuit 10 of the embodiment includes a four-phase input/output RC poly-phase filter (hereinafter simply referred to as “poly-phase filter”). The signals with phase differences of 0°, 90°, 180° and 270° from first to fourth output terminals 11e to 11h are obtained from the poly-phase filter 11, when signals with phase differences of 0° and 180° are input from first to fourth input terminals 11a to 11d.

A resistive load circuit 12 is connected between a power supply terminal 14 and the first to fourth output terminals 11e to 11h, and converts output currents to the poly-phase filter 11 into voltages output.

A four-phase input/output transconductance amplifier (hereinafter simply referred to as “transconductance amplifier”) 13 is connected between the first to fourth input terminals 11a to 11d and a reference potential GND. The transconductance amplifier 13 provides signals with phase differences of 0° and 180° to the poly-phase filter 11.

The poly-phase filter 11 has resistors R1 to R4 and capacitors C1 to C4, which are connected between the first to fourth input terminals 11a to 11d and the first to fourth output terminals 11e to 11h.

The resistors R1 to R4 are connected between the first to fourth input terminals 11a to 11d and the first to fourth output terminals 11e to 11h, respectively. One port of the capacitors C1 to C4 are connected to the first to fourth input terminals 11a to 11d. The other port of the capacitors C1 to C4 are connected to output terminals of the poly-phase filter 11 which are not paired with the first to fourth input terminals 11a to 11d respectively, as described below.

Specifically, the resistor R1 is connected between the first input terminal 11a and the first output terminal 11b. The capacitor C1 is connected between the first input terminal 11a and the second output terminal 11f. The resistor R2 is connected between the second input terminal 11b and the second output terminal 11f. The capacitor C2 is connected between the second input terminal 11b and the third output terminal 11g.

Similarly, the resistor R3 is connected between the third input terminal 11c and the third output terminal 11g. The capacitor C3 is connected between the third input terminal 11c and the fourth output terminal 11h. The resistor R4 is connected between the fourth input terminal 11d and the fourth output terminal 11h. The capacitor C4 is connected between the fourth input terminal 11d and the first output terminal 11e.

The value of the resistors R1 to R4 is same, and defines as R, for example. Also, the value of the capacitors C1 to C4 is same, and defines as C, for example.

The poly-phase filter 11 has a characteristic of passing the signal at a cut-off frequency of f (=1/2πRC). The frequency f is determined by a value of the resistance R and the capacitance C. The signals of IN_ip and IN_qp have a phase difference of 0° from the input ports of 11a and 11b, respectively. Also, the signals of IN_in and IN_qn have a phase difference of 180° from the input ports of 11c and 11d, respectively. As will be described below, both IN_ip and IN_qp have a different input port, the poly phase filter operates even they have a same signal. Equally, IN_in and IN_qn have a different input port, the poly phase filter operates even they have a same signal.

A signal with a phase difference of 0° is obtained at the output to the first output terminal 11e, that of 90° from the second output terminal 11f, that of 180° from third output terminal 11g, and that of 270° from the forth output terminal 11h.

When the frequency of f is different from the desired frequency because of the process mismatch of the resistor R and the capacitor C, it is possible to adjust the f to the desired frequency with varying current sources. The target system of the desired frequency is 5.8 GHz, and it is used for the mobile communication system, for example.

A resistive load circuit 12 includes load resistors RL1 to RL4 connected between a power supply terminal 14 and the first to fourth output terminals 11e to 11h of the poly-phase filter 11, respectively. Resistance values of the load resistors RL1 to RL4 are set equal to each other.

Specifically, the load resistor RL1 is connected between the first output terminal 11e and a wiring 15 of a higher potential which extends to the power supply terminal 14. The load resistor RL2 is connected between the second output terminal 11f and the wiring 15.

Similarly, the load resistor RL3 is connected between the first output terminal 11g and the wiring 15. The load resistor RL4 is connected between the second output terminal 11h and the high potential wiring 15.

The transconductance amplifier 13 converts a voltage signal to a current signal. The transconductance amplifier 13 includes a first differential amplifier 16 and a second differential amplifier 17.

The first differential amplifier 16 includes a pair of differentially connected N channel insulated gate field-effect transistors (hereinafter simply referred to as “MOS transistors”) M1, M2, and a first constant current source 18.

The first constant current source 18 is connected between sources of the MOS transistors M1, M2 and the reference potential GND. As will be described below, the first constant current I1 flows from the first constant current source 18, can be varied by a control signal.

Two output terminals of the first differential amplifier 16 are connected to the first and third input terminals 11a, 11c. The output terminals correspond to drains of the MOS transistors M1, M2 of the first differential amplifier 16.

A signal IN_ip with a phase difference of 0° and a signal IN_in with a phase difference of 180° are from both input terminals of the first differential amplifier 16. The input terminals correspond to gates of MOS transistors M1, M2 of the first differential amplifier 16.

Similarly, the second differential amplifier 17 includes a pair of differentially connected MOS transistors M3, M4 and a second constant current source 19. A second constant current I2 can be varied by a control signal.

The second constant current source 19 is connected between sources of the MOS transistors M3, M4 and the reference potential GND. The second constant current source 19 provides first constant current I2 which can be varied by a control signal.

Two output terminals of the second differential amplifier 17 are connected to the second and fourth input terminals 11b, 11d. The output terminals correspond to drains of the MOS transistors M3, M4.

A signal IN_ip with a phase difference of 0° and a signal IN_in having a phase difference of 180° are from both input terminals of the MOS transistors M3, M4 of the second differential amplifier 17, respectively. The input terminals correspond to gates of the MOS transistors M3, M4, respectively.

The first constant current I1 and the second constant current I2 have a same value.

The signal IN_ip with the phase difference of 0° and the signal IN_in with that of 180° are generated by frequency multiplier or frequency divider from an output signal of the voltage controlled oscillator (not shown), for example.

The IQ signal generation circuit 10 generates IQ signals with a sufficient signal level and a small phase error. The IQ signal generation circuit 10 can vary phases of the IQ signals in order to obtain phase differences of 90° at desired frequency.

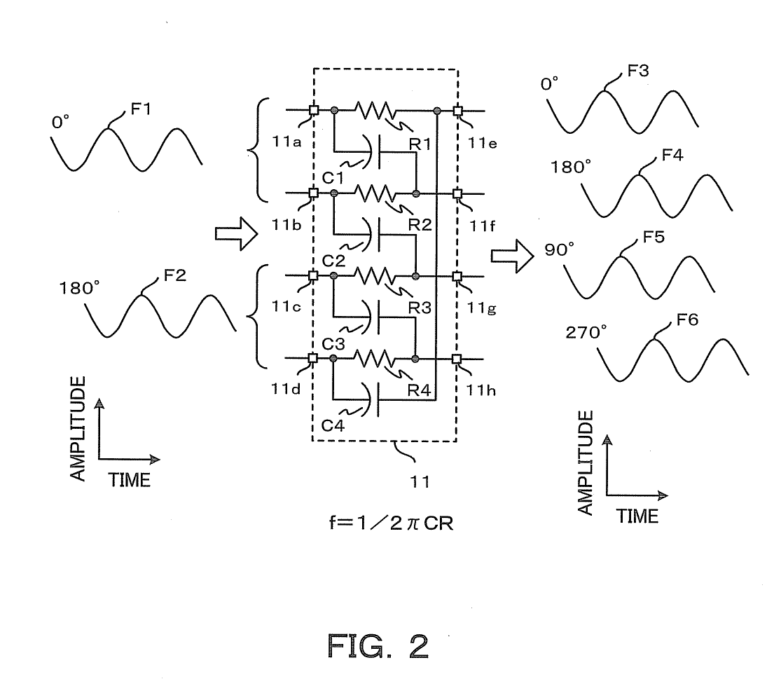

FIG. 2 shows an example of input/output characteristics of the poly-phase filter 11. As shown in FIG. 2, signals of a frequency f (=1/2πRC) passes through the poly-phase filter 11. A signal F1 with a phase difference of 0° is able to pass from the first and second input terminals 11a, 11b. A signal F2 with a phase difference of 180° is able to pass from the third and fourth input terminals 11c, 11d.

Signals F3 to F6 with phase differences of 0°, 180°, 90° and 270° are generated to the first to fourth output terminals 11e to 11h, due to high-pass and low-pass filter effects based on a product of resistance values of the resistors R1 to R4 and capacitance values of the capacitors C1 to C4.

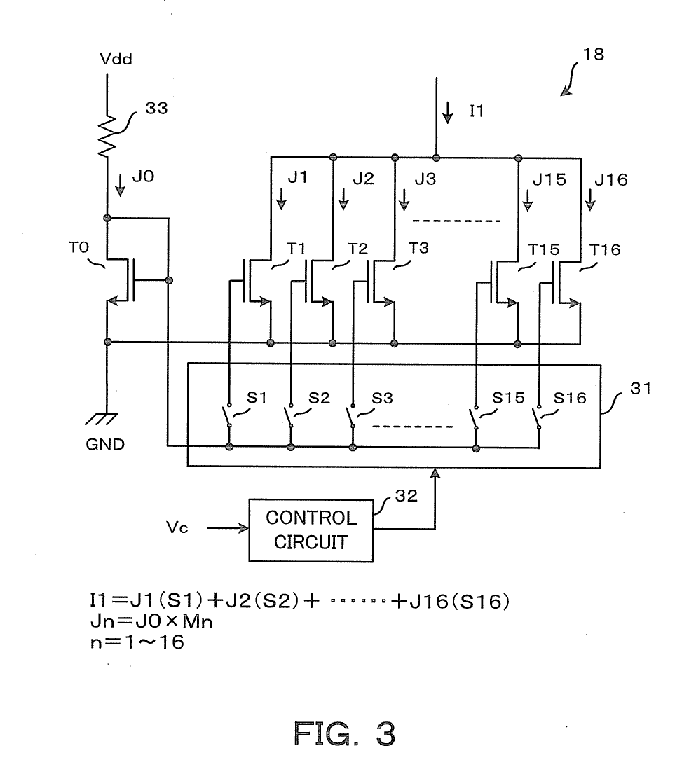

FIG. 3 shows is a circuit diagram of the first constant current source 18. As shown in FIG. 3, the first constant current source 18 is a current mirror which has a multiple output. A first constant current (output current) I1 of the first constant current source 18 can be varied by a control signal Vc. The first constant current source 18 includes MOS transistors T0 to T16, a current-limiting resistor 33, a switch circuit 31 and a control circuit 32.

A drain and a gate of the MOS transistor T0 are connected to each other. Output current J0 flows through the MOS transistor T0 and a current-limiting resistor 33. A control circuit 32 generates control signal which turns on or off of the switches of S1 to S16 in the switch circuit 31, based on the control signal Vc.

Gates of the MOS transistors T1 to T16 are selectively connected to the gate of the MOS transistor T0, based on ON and OFF state of the switches of S1 to S16. Output currents J1 to J16 flow through the MOS transistors T1 to T16.

As the switches S1 to S16, MOS transistors with low operation voltage can be used. The control signal Vc is a binary signal of four bits, for example. The control circuit 32 decodes four bit binary signal of the control signal Vc, and turns the switches S1 to S16 ON by the decoded signals.

The first constant current I1 is expressed by the following equation. The switch of Sn turns on when Sn is 1 (one). And, the switch of Sn turns off, when Sn is 0 (zero). Mn indicates a mirror ratio.

I1=J1(S1)+J2(S2)+ . . . J16(S16) (1)

Jn=J0×Mn, n=1 to 16 (2)

Hence, when all of the mirror ratios are set to 1 (Mn=1), the first constant current I1 can be varied with 16 steps from 0 to 16J0.

The second constant current source 19 has a similar circuit configuration as that of the first constant current source 18. The control signal of Vc of the second constant current source 19 is the signal which is inverted from the control signal of the first constant current I8. When the switch Sn (n=1 to 16) of the first constant current source 18 is ON, the switch Sn (n=1 to 16) of the second constant current source 19 is OFF. Then, the first constant current I1 can increase or decrease complementary with the second constant current I2.

When a value of the first constant current I1 is varied, transconductances of the differentially-connected MOS transistors M1, M2 are varied. When the first constant current I1 is decreased, the transconductances of the MOS transistors M1, M2 are decreased. When the first constant current I1 is increased, the transconductances of the MOS transistors M1, M2 are increased.

In this case, the impedance of the transconductances of the MOS transistors M1, M2 are dominant looking from poly phase filter 11 to transconductance amplifier 13

Similarly, the second constant current I2 and the transconductances of the MOS transistors M3, M4 are also same as noted above.

Following is a reason why the values of the first and second constant currents I1, I2 are varied in the reverse manner. The rate of the variation ΔR among value of resistance R is able to increase or decrease, because of increasing or decreasing the value of the transconductances of the MOS transistors M1 to M4.

When both of the values of the first and second constant currents I1 and I2 are increased or decreased, the cut-off frequency is able to adjust with varying the transconductances of the transconductance amplifier 13. However, cut-off frequency is able to adjust in wideband with varying the current of the constant current of I1 and I2, considered from the purpose of changing the rate of the variation of ΔR among the value of resistance R, noted above.

In this case, the variation amount ΔR shows variations of the resistance values of the poly-phase filter 11. When these resistance values are varied in the same direction, the phase difference between quadric phase signal is not able to be 90°, because the transconductances of I-signal pass and Q-signal pass have a same amount of change.

When the transconductances of the transconductance amplifier 13 are varied, resistance values R of the resistors R1 to R4 of the poly-phase filter 11 are equivalently varied. As a result, the cut-off frequencies of the output signals are varied.

Each frequency of the output signals is expressed by the following equation.

f=1/2π(R+ΔR)C (3)

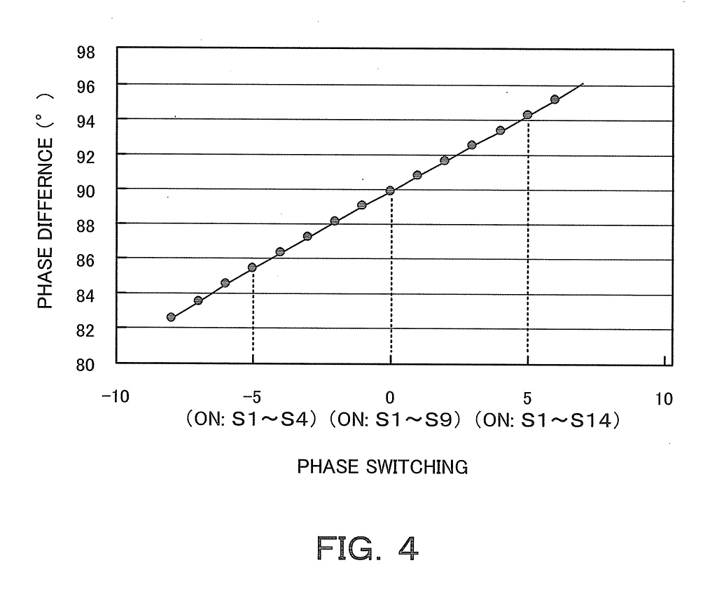

FIG. 4 shows a simulation result of variation of the phase difference at a target frequency of the IQ signals. The simulation was carried out by a harmonic balance analyzing method where the target frequency was set to 5.8 GHz.

In FIG. 4, the horizontal axis depicts the number of the on-state switches based in that of S1 to S9, corresponding with four bit controlling signal of Vc. For example, “−5” indicates from S1 to S4 are on-state, “0” indicates from S1 to S9 are on-state, and “5” indicates from S1 to S14 are on-state. FIG. 4 shows, the phase difference of the IQ signals is able to change depending on the number of the on-state or off stateswitches.

Since the poly-phase filter 11 is inserted into a current transmitting passage, an effect of parasitic capacitance can be suppressed. Also, the parasitic resistance can be suppressed because the resistance value of the poly phase filter R is dominant in the transmitting pass.

Therefore, the phase errors between IQ signals are suppressed considerably in the IQ signal generation circuit 10 of the embodiment. It is possible to correct the error between target frequency and the undesired frequency which has a phase difference of 90° between IQ signals with increasing or decreasing the current of the first and second constant currents of I1 and I2, complementary. The frequency error is caused by the process tolerance of resistance value of R and capacitance value of C.

Moreover, the IQ signal generation circuit 10 of the embodiment has a high common mode rejection ratio because it includes the transconductance amplifier 13 and the first and second differential amplifiers 16 and 17.

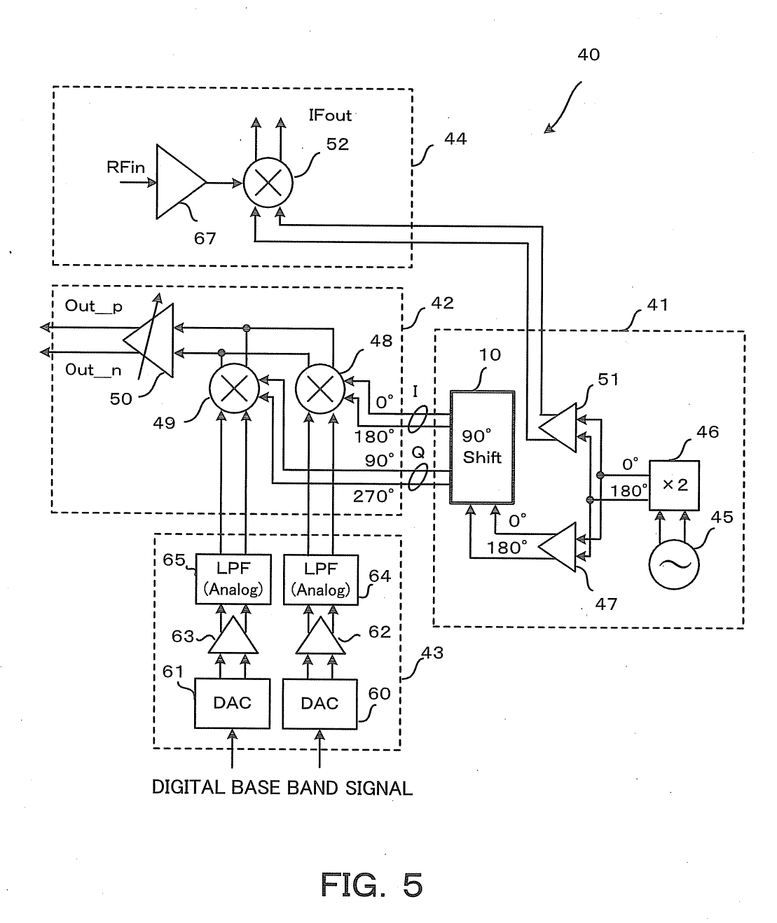

FIG. 5 shows a block diagram of an IQ modulator/demodulator using the IQ signal generation circuit 10 of the first embodiment. As shown in FIG. 5, the IQ modulator/demodulator 40 is composed of a signal generation circuit 41, an IQ modulation circuit 42, a base-band circuit 43 and an IQ demodulator 44.

The signal generation circuit 41 generates a high-harmonic signal which is used as a carrier. The base-band circuit 43 includes a base-band signal to the IQ modulation circuit 42.

The signal generation circuit 41 includes a local oscillation circuit 45 which has a voltage controlled oscillator (VCO), and a frequency multiplier 46. The local oscillation circuit 45 generates a differential signal at a frequency of 2.9 GHz as a carrier signal. The frequency multiplier 46 multiplies the differential signal at the frequency of 2.9 GHz, and generates signals with phase differences of 0° and 180° and having a frequency of 5.8 GHz.

The IQ signal generation circuit 10 has an input signal with phase differences of 0° and 180° through a differential buffer 47, for example. Then, the IQ signal generation circuit 10 generates I signals with the phase differences of 0° and 180°, and further generates Q signals with phase differences of 90° and 270°. The differential buffer 47 can be connected to a subsequent stage of the IQ signal generation circuit 10.

In the IQ modulation circuit 42, I-mixer 48 has input of I signals, and Q-mixer 49 has input of Q signals. The I-mixer 48 mixes the I signals and a base-band signal from the base-band circuit 43. The Q-mixer 49 mixes the Q signals and a base-band signal from the base-band circuit 43.

In the base-band circuit 43, digital base-band signals are converted into analogue signals by digital-to-analogue converter (DAC) 60, 61. The buffers 62, 63 have input converted signals, pass through low-pass filters 64, 65 and generate analogue base-band signals. The I-mixer 48 and Q-mixer 49 have an output signals from the bas-band signals.

The base-band signals and mixed I-signals or Q-signals are amplified by a differential amplifier 50 each other, and have a differential output power of Out_p and Out_n.

On the other hand, mixer 52 in the IQ demodulator 44 has an input signal from signal generation circuit 41, which signal is generated in the local oscillator 45 with phase difference of 0° and 180°. Buffer 67 in the demodulator 44 has an input signal from the received high frequency signal RFin. The mixer 52 mixes an output signal of the buffer 67 and the signals with having the phase differences of 0° and 180°. The mixer has an output signal which generated as an intermediate frequency signal IFout.

In FIG. 5, the demodulation circuit 44 is not an IQ demodulator, but an IQ demodulator can be employed instead.

In the IQ signal generation circuit 10 of the first embodiment, the signals with phase differences of 0° and 180° are converted from voltage to current and amplified to sufficient level in the transconductance amplifier 13, then pass through the poly-phase filter 11.

Hence, it is possible to obtain IQ signals with sufficient signal levels and small phase errors.

The poly-phase filter 11 is composed in the current transmitting passage, the effect of parasitic capacitance is suppressed. The transconductances of the transconductance amplifier 13 are dominant so that the effect of parasitic resistance in the current transmitting passage is suppressed. Further, the transconductance amplifier 13 has high common mode rejection ratio.

In addition, the first constant current I1 of the first differential amplifier 16 and the second constant current I2 of the second differential amplifier 17 are able to increase or decrease complementary, then the resistance value R of the poly-phase filter 11 can be varied in same matter, then the phase of the IQ signals is able to adjust.

Even the frequency where the phase differences of IQ signals is 90° is varied due to the process tolerance of the resister R or capacitor C in poly-phase filter 11, it is possible to tune desired IQ signals in target frequency.

The first and second currents I1 and I2 is increased or decreased in the embodiment, it is also able to fix the current of one of the constant current and vary the other constant current.

The MOS transistors M1 to M4 and the MOS transistors T0 to T16 are N-channel MOS transistors in the embodiment, it is also possible to use P-channel MOS transistors.

Instead of the MOS transistor which is differentially connected transistors M1 to M4 used in the first and second differential amplifier 16, 17, bipolar transistors are also able to use.

Specifically, the first differential amplifier 16 can be composed of a pair of NPN bipolar transistors with a base, an emitter and a collector. The bases of the NPN bipolar transistors receive the signals IN_ip and IN_in respectively. The emitters of the NPN bipolar transistors are connected to the first constant current source 18. The collectors of the NPN bipolar transistors are connected to the first and the third input terminals 11a, 11c respectively.

Further, the second differential amplifier 17 is composed of a pair of NPN bipolar transistors with a base, an emitter and a collector. The bases of the NPN bipolar transistors receive the signals IN_qp and IN_qn respectively. The emitters NPN bipolar transistors are connected to the second constant current source 19 respectively. The collectors NPN bipolar transistors are connected to the second and the fourth input terminals 11b, 11d respectively.

The poly-phase filter 11 is possible to increase the number of stages. In the case, the accuracy of output IQ signals is possible to be increased.

If the number of stage of the poly-phase filter is increased, MOS transistors M1 to M4 is not able to operate in saturation region because of the large voltage drop in the load resistance RL1 to RL4, and resistance R1 to R4. Therefore, two or three stages are desirable.

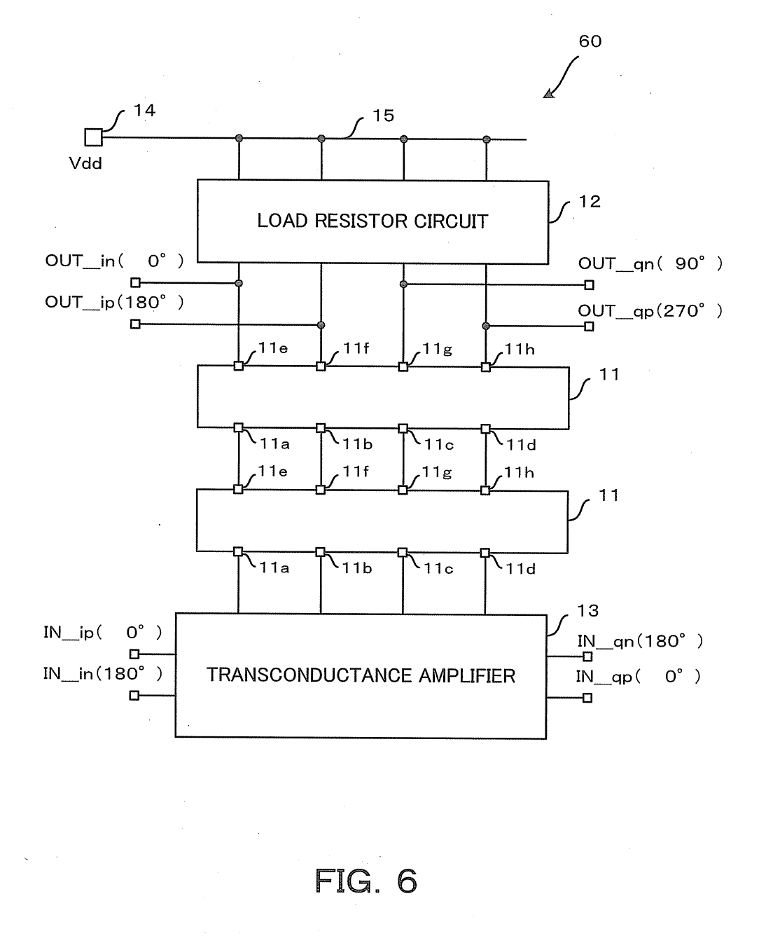

FIG. 6 shows a circuit diagram of another IQ signal generation circuit of the first embodiment which a plurality of poly-phase filters is cascade-connected. As shown in FIG. 6, in the IQ signal generation circuit 60, two poly-phase filters 11 are cascade-connected.

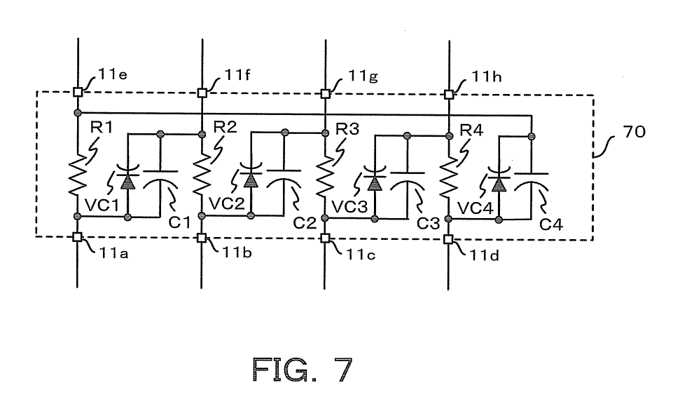

An IQ signal generation circuit of a second embodiment will be described. FIG. 7 shows a circuit diagram with a poly-phase filter composed of the IQ signal generation circuit of the second embodiment. In the second embodiment, capacitance of the poly-phase filter can equivalently be varied.

As shown in FIG. 7, the variable capacitors VC1 to VC4 and the capacitors C1 to C4 are connected in parallel in the poly-phase filter 70 of the second embodiment. The configuration of the circuit is same as FIG. 1 except poly-phase filter 70.

The bias voltages are applied between the variable capacitors VC1 to VC4 and resistors R1 to R4. It is possible to adjust output frequency which the phase differences of 90° are obtained, from tuning the capacitors C1 to C4 with applying the bias voltage.

In this case, frequencies of the output signals are expressed by the following equation. ΔR represents a variation amount of the capacitance C. ΔR is tuned by the bias voltages to tune the frequency f is adjusted to the target frequency.

f=1/2πR(C+ΔR) (4)

In the second embodiment, the input terminals 11a to 11d of the poly-phase filter 70 are connected to MOS transistors M1 to M4 shown in FIG. 1, respectively.

Two transconductances of the MOS transistors M1, M2 and each transconductances of the MOS transistors M3, M4 are increased and decreased with first and second constant currents I1, I2 in the reverse manner. Therefore, it is possible to equivalently vary the resistance value R of the poly-phase filter 70. In this case, each frequency of the output signals with phase differences of 90° are expressed by the following equation. The second embodiment has an advantage that IQ signal generation circuit has a wideband operation range because of the wideband frequency range of the poly-phase filter compared with the first embodiment shown in FIG. 1.

f=1/2π(R+ΔR)(C+ΔC) (5)

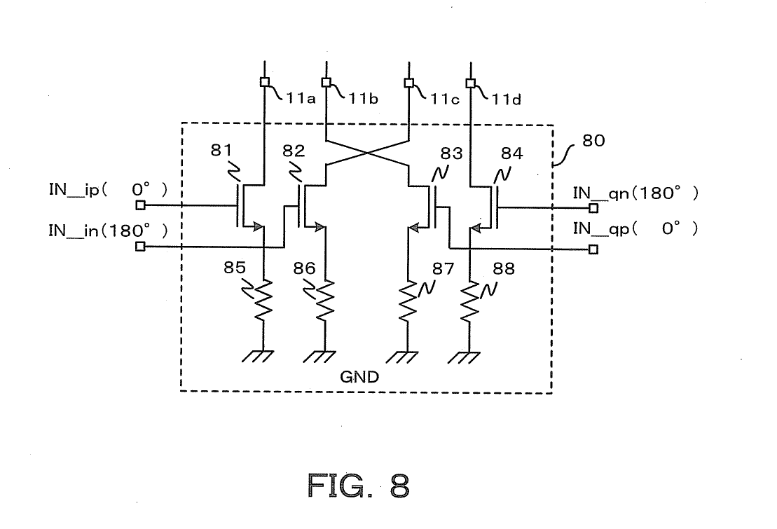

An IQ signal generation circuit according to a third embodiment will be described. FIG. 8 depicts a circuit diagram of a transconductance amplifier using in the IQ signal generation circuit of the third embodiment.

According to the third embodiment, the transconductance amplifier is composed of MOS transistors which are not connected to each other, as will be described below.

As shown in FIG. 8, in the transconductance amplifier 80 of the third embodiment, MOS transistors 81 to 84 are connected between first to fourth input terminals 11a to 11d and a reference potential GND through resistors 85 to 88, respectively.

Signals IN_ip and IN_qp have a signal input with phase differences of 0°, and connect to gates of MOS transistors 81, 83. Signals IN_in and IN_qn have a signal input with phase differences of 180°, and connect to gates of the MOS transistors 82, 84.

In the third embodiment described above, the transconductance of the transconductance amplifier 80 is not variable unlike the first and second embodiments. However, the circuit configuration of the transconductance amplifier 80 is simpler than the first and second embodiments, and the production of the transconductance amplifier is able to product with ease.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An IQ signal generation circuit, comprising:
an RC poly-phase filter provided with first to fourth input terminals and first to fourth output terminals, and resistors and capacitors respectively connected between the first to fourth input terminals and the first to fourth output terminals, the first and second input terminals receiving first signals with a phase difference of 0°, the third and fourth input terminals receiving second signals with a phase difference of 180°, the first to fourth output terminals generate first to fourth output signals with phase differences of 0°, 90°, 180° and 270°;
a resistance load circuit connected between the first to fourth output terminals and a power supply terminal; and
a transconductance amplifier connected between the first to fourth input terminals and a reference voltage terminal to receive third and fourth input signals corresponding to the first and second signals, the transconductance amplifier amplifies the third and fourth input signals and provides the amplified signals to the first and second input terminals, and to the third and fourth input terminals, respectively.

2. The IQ signal generation circuit according to claim 1, further comprising at least one more RC poly-phase filter similar to the RC poly-phase filter, wherein the RC poly-phase filters is cascade-connected between the resistive load circuit and the transconductance amplifier.

3. The IQ signal generation circuit according to claim 1, further comprising variable-capacitance diodes, wherein the variable-capacitance diodes are connected to the capacitors in parallel, respectively.

4. An IQ signal generation circuit, comprising:
an RC poly-phase filter included with first to fourth input terminals and first to fourth output terminals, first to fourth resistors and first to fourth capacitors respectively connected between the first to fourth input terminals and the first to fourth output terminals, the first and second input terminals receiving first signals with a phase difference of 0°, the third and fourth input terminals receiving second signals with a phase difference of 180°, the first to fourth output terminals generate the signal of third to sixth output with phase differences of 0°, 90°, 180° and 270°;
a resistive load circuit connected between the first to fourth output terminals and a power supply terminal; and
a transconductance amplifier connected between the first to fourth input terminals and a reference voltage terminal, and included with first and second differential amplifiers, wherein
two output terminals of the first differential amplifier are connected to the first and third input terminals respectively to receive seventh and eighth input signals, the first differential amplifier including amplified signals to the first and third input terminals respectively as one of the first signals and one of the second signals, and
two output terminals of the second differential amplifier are connected to the second and fourth input terminals respectively to receive the seventh and eighth input signals, the second differential amplifier providing amplified signals to the third and fourth input terminals respectively as the other of the first signals and the other of the second signals.

5. The IQ signal generation circuit according to claim 4, wherein first and second currents provided to the first and second differential amplifiers are generated from first and second constant-current sources which can vary an output current by a control signal.

6. The IQ signal generation circuit according to claim 5, wherein at least one of the first and second constant-current sources includes:
a first insulated gate field-effect transistor including a first gate, a first source and a first drain, the first drain and the gate being connected to each other, the first drain being connected to the power supply terminal, and the first source being connected to the reference voltage terminal, and
a plurality of second insulated gate field-effect transistors provide with a second gate, a second source and a second drain, respectively, each second source being connected to the reference voltage terminal, each second gates being selectively connected to the first gate of the first insulated gate field-effect transistor based on the control signal, at least one of the first and second currents is obtained based on currents flowing through at least one of the second drains of the second insulated gate field-effect transistors.

7. The IQ signal generation circuit according to claim 4, wherein the second gates can be connected to the first gate of the first insulated gate field-effect transistor through switches, and each of the switches turns the second insulated gate field-effect transistor ON and OFF by control signals generated by a control circuit which operates based on the control signal.

8. The IQ signal generation circuit according to claim 4, further comprising at least one more RC poly-phase filter similar to the RC poly-phase filter, wherein the plurality of RC poly-phase filters is cascade-connected between the resistance load circuit and the transconductance amplifier.

9. The IQ signal generation circuit according to claim 4, further comprising variable-capacitance diodes, wherein the variable-capacitance diodes are connected to the capacitors in parallel, respectively.

10. The IQ signal generation circuit according to claim 5, wherein the output currents of the first and second constant-current sources can be increased and reduced by the control signal in a reverse manner.

11. The IQ signal generation circuit according to claim 5, wherein each of the first and second differential amplifiers is provided with a pair of third insulated gate field-effect transistors respectively having a third gate, a third source and a third drain, each third gate receiving the seventh and eighth signals, each third source being connected to the first or second constant-current source, and each third drain being connected to the first and third input terminals or the second and fourth input terminals.

12. The IQ signal generation circuit according to claim 5, wherein each of the first differential amplifier is provided with a pair of first bipolar transistors respectively having a first base, a first emitter and a first collector, the first bases receiving the seventh and eighth signals respectively, the first emitters being connected to the first constant-current source, the first collectors being connected to the first or third constant-current source.

13. An IQ signal generation circuit, comprising:
an RC poly-phase filter provide with first to fourth input terminals and first to fourth output terminals, and first to fourth resistors and first to fourth capacitors respectively connected between the first to fourth input terminals and the first to fourth output terminals, the first and second input terminals receiving first signals having a phase difference of 0°, the third and fourth input terminals receiving second signals having a phase difference of 180°, the first to fourth output terminals outputting third to sixth output signals having phase differences of 0°, 90°, 180° and 270°,
a resistance load circuit connected between the first to fourth output terminals and a power supply terminal,
a transconductance amplifier provided with first to fourth series circuits connected between the first to fourth input terminals and a reference voltage terminal, respectively, the first series circuit having a first insulated gate field-effect transistor and a fifth resistor connected in series with each other, the second series circuit connects a second insulated gate field-effect transistor and a sixth resistor connected in series with each other, the third series circuit having a third insulated gate field-effect transistor and a seventh resistor connected in series with each other, the fourth series circuit having a fourth insulated gate field-effect transistor and an eighth resistor connected in series with each other, and one ends of the fifth to eighth resistors being connected to the reference voltage terminal, wherein
the gates of the first and third insulated gate field-effect transistors receive a seventh input signal, amplify the seventh input signal, and provide amplified signals from the respective drains to the first and second input terminals as the first signals, and
the gates of the second and fourth insulated gate field-effect transistors receive an eighth input signals, amplify the eighth signal, and provide amplified signals from the respective drains to the third and fourth input terminals as the second signals.

14. The IQ signal generation circuit according to claim 15, further comprising at least one more RC poly-phase filter similar to the RC poly-phase filter, wherein the plurality of RC poly-phase filters is cascade-connected between the resistive load circuit and the transconductance amplifier.

15. The IQ signal generation circuit according to claim 13, wherein the second gates can be connected to the first gate of the first insulated gate field-effect transistor through switches, and each of the switches turns the second insulated gate field-effect transistor ON and OFF by control signals generated by a control circuit which operates based on the control signal.
